(19) United States
(12) Patent Application Publication
(10) Pub. No.: US 2024/0353507 A1
(43) Pub. Date: Oct. 24, 2024

(54) Magnetometer Array System For Small Satellites

(71) Applicant: THE REGENTS OF THE UNIVERSITY OF MICHIGAN, Ann Arbor, MI (US)

(72) Inventors: Matthew Joseph PELLIONI, Baltimore, MD (US); Finna Hope BRONNER, Rockville, MD (US); Jacob THOMA, Pasadena, CA (US); Leonardo REGOLI, Laurel, MD (US); Brady STRABEL, Kentwood, MI (US); Lauro V. OJEDA, Ann Arbor, MI (US); Mark B. MOLDWIN, Ann Arbor, MI (US)

(21) Appl. No.: 18/636,339

(22) Filed: Apr. 16, 2024

Related U.S. Application Data
(60) Provisional application No. 63/461,361, filed on Apr. 24, 2023.

(51) Int. Cl. G01R 33/00; G01R 33/10

(52) U.S. Cl. CPC G01R 33/0094; G01R 33/10

(57) ABSTRACT

A CubeSat magnetometer array system having a housing having CubeSat dimensions, a host computer, and a magnetometer array system. The magnetometer array system includes a circuit board mounted within the housing, a plurality of magnetometers operably mounted on the circuit board, and a microcontroller system operably coupled with the plurality of magnetometers. The microcontroller system is configured to synchronize data from the plurality of magnetometers, utilize machine learning processes to identify and reduce noise in the synchronized data, and output a signal representative of a magnetic field with reduced noise due to the machine learning processes. A communication interface is operably coupled with the host computer and the microcontroller system and configured to communicate the signal to the host computer.

### CROSS-REFERENCE TO RELATED APPLICATIONS

This application claims the benefit of U.S. Provisional Application No. 63/461,361, filed on Apr. 24, 2023. The entire disclosure of the above application is incorporated herein by reference.

### GOVERNMENT INTEREST

This invention was made with government support under 80NSSC18K1240 awarded by the National Aeronautics and Space Administration. The government has certain rights in the invention.

### FIELD

The present disclosure relates to magnetometers and, more particularly, relates to a magnetometer array system for small satellite applications.

### BACKGROUND & SUMMARY

This section provides background information related to the present disclosure which is not necessarily prior art. This section provides a general summary of the disclosure, and is not a comprehensive disclosure of its full scope or all of its features.

Measuring magnetic fields in space is required to understand most heliophysics and space physics systems. From the interplanetary medium down to the upper layers of planetary ionospheres, the interaction between charged particles and magnetic fields defines the motion of charged particles, the convection of plasmas, and the generation and damping of waves. An important limitation of traditional space missions, when studying the dynamic nature of the space environment, is the inability to sample more than one point in space at any given time. This makes it difficult to disentangle multiple signals from different sources.

In recent years, multi-spacecraft missions have been launched to study different aspects of the Earth's magnetosphere. Given the prominent role of magnetic fields, these missions were equipped with high-resolution science magnetometers. Different technological developments have led to smaller magnetometers with the capability of measuring fields with very high resolution, which was impossible to achieve a couple of decades ago.

A CubeSat is a class of small satellite with a form factor of 10 cm (3.9 in) cubes. CubeSats have a mass of no more than 2 kg (4.4 lb) per unit, and often use commercial off-the-shelf (COTS) components for their electronics and structure. CubeSats are deployed into orbit from the International Space Station or launched as secondary payloads on a launch vehicle.

The relatively low cost associated with CubeSat instruments makes them desirable for multi-spacecraft studies. However, due to their small size, any system designed to be used in a CubeSat needs to not only be small but also have very low power consumption (due to the limited area for solar panels). In addition, for a CubeSat mission to take advantage of the low-cost concept, the production price for any instrument needs to be minimized.

Several approaches have been used to obtain magnetic field measurements with a resolution sufficiently high to perform scientific studies of the magnetosphere. In general, these approaches can be summarized in two main categories, namely, miniaturization of traditional fluxgate and helium magnetometers and the use of commercial off-the shelf (COTS) sensors.

The present disclosure addresses the latter approach, namely use of commercial off-the-shelf componentry. The present teachings describe not only the use of a small-size, lightweight, and low-power and cost (SWAP+C) chip-based COTS magnetometer, but also the combination of multiple magnetometers into a single system to improve the resolution by oversampling with multiple sensors. The present teachings overcome the disadvantages of previous work that was constrained by circuit board errors and incomplete characterization. Moreover, magnetic interference testing for the complete system is also examined as a performance gauge.

According to the principles of the present teachings, a CubeSat form factor magnetometer is provided having a plurality of magneto-inductive magnetometers coupled with innovative machine learning magnetic noise identification algorithms enables both spacecraft attitude determination and research quality magnetic observations from small satellites without booms. The plurality of sensors on a single printed circuit board with a micro-controller provides increased resolution while maintaining low-power, mass, and size characteristics.

In some embodiments, according to the principles of the present teachings, a CubeSat magnetometer array system is provided having a CubeSat-sized housing, a host computer, and a magnetometer array system. The magnetometer array system includes a circuit board mounted within the housing, a plurality of magnetometers operably mounted on the circuit board, and a microcontroller system operably coupled with the plurality of magnetometers. The microcontroller system is configured to synchronize data from the plurality of magnetometers, utilize machine learning processes to identify and reduce noise in the synchronized data, and output a signal representative of a magnetic field with reduced noise due to the machine learning processes. A communication interface is operably coupled with the host computer and the microcontroller system and configured to communicate the signal to the host computer.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 illustrates a circuit diagram of a conventional magneto-inductive (MI) sensor.

FIG. 2 illustrates conventional magneto-inductive (MI) sensor circuit response with external field applied.

FIGS. 3A-3B are top and bottom views, respectively, of a Multi-Mag system according to some embodiments of the present teachings.

FIG. 4 is a top view of a Multi-Mag system according to some embodiments of the present teachings.

FIGS. 5A-5B illustrate communication packet formats for communication with the Multi-Mag system.

FIGS. 6A-6B illustrate a Zero Gauss chamber and copper room used for resolution test.

FIGS. 7A-7C illustrate Multi-Mag system resolution test data at 65 Hz.

FIGS. 8A-8C illustrate Multi-Mag system resolution test data at 1 Hz.

FIGS. 9A-9C illustrate Multi-Mag system power spectral density.

FIGS. 10A-10C illustrate Multi-Mag system stability test data.

FIGS. 11A-11B illustrate companion magnetometer interference test data.

FIGS. 12A-12B illustrate board interference test data.

Corresponding reference numerals indicate corresponding parts throughout the several views of the drawings.

### DETAILED DESCRIPTION

Example embodiments will now be described more fully with reference to the accompanying drawings. Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected, or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

According to the principles of the present teachings, a magnetometer array system 10 having a CubeSat form factor and a multi-magnetometer system 20 (“Multi-Mag system”) is provided having advantageous construction and method of operation. In some embodiments, CubeSat magnetometer array system 10 comprises a housing structure, power source, communication links, and electronic componentry configured to operably couple with Multi-Mag system 20 disposed within the housing structure.

It should be understood that although the principles of the present teachings, namely the Multi-Mag system, will be described in connection with CubeSat type applications, the principles of the present teaching have application in a wide variety of applications, including but not limited to ground magnetometers at high altitudes where 1 nT resolution at 1 Hz is sufficient to measure most geomagnetic disturbances of interest.

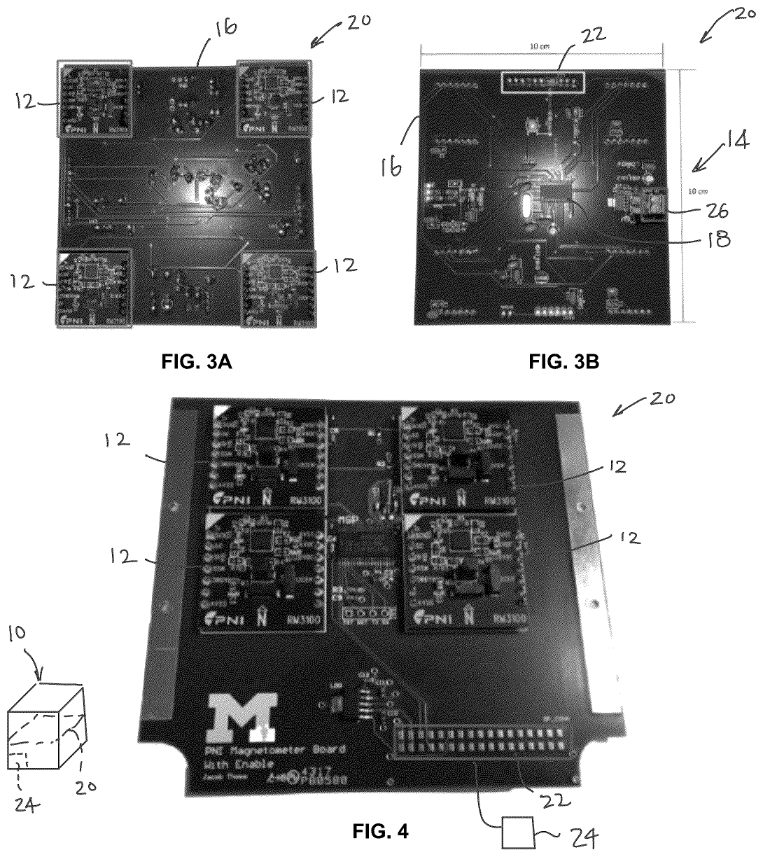

In some embodiments, as illustrated in FIGS. 3A, 3B, and 4, the Multi-Mag system 20 of CubeSat magnetometer array system 10 comprises a plurality of (in some embodiments, two, three, four, or more) magneto-inductive magnetometers 12 coupled with innovative machine learning magnetic noise identification algorithms via a microcontroller system 14. In some embodiments, Multi-Mag system 20 enables both spacecraft attitude determination and research quality magnetic observations from a small satellite without the need for conventional external booms. In some embodiments, the plurality of magnetometers 12 of Multi-Mag system 20 are mounted on a single printed circuit board 16 with the microcontroller system 14, and associated microcontroller 18, formed thereon to provide increased resolution while maintaining low-power, mass, and size characteristics. The combination of the plurality of magnetometers 12, the microcontroller system 14, and microcontroller 18 mounted on single printed circuit board 16 will be referred to as Multi-Mag system 20. In accordance with the principles of the present teachings, Multi-Mag system 20 provides advantageous construction and method of operation.

In some embodiments, as illustrated in FIGS. 3B and 4, Multi-Mag system 20 of CubeSat magnetometer array system 10 comprises a communication interface 22, such as a simple Universal Asynchronous Receiver-Transmitter (UART) interface, operable and configured to facilitate two-way communication, including command signals and data signals, between Multi-Mag system 20 and other CubeSat componentry. In some embodiments, communication interface 22 can comprise six wired connections to the CubeSat, including two UART lines, two debugging lines, and power/ground lines. In some embodiments, communication interface 22 can comprise a male to female connection with the CDH bus of the satellite, eliminating wire connections.

Additionally, in some embodiments, Multi-Mag system 20 of CubeSat magnetometer array system 10 can comprise a power interface 26.

In some embodiments, Multi-Mag system 20 can comprise four (4) magnetometers 12, each being a PNI Sensor RM3100 (hereinafter, “RM3100”), and microcontroller 18, being a Texas Instrument MSP430FR5949. In some embodiments, Multi-Mag system 20 is operable and configured to detect and help study the Earth's geomagnetic field, field-aligned currents, and ULF waves. The inclusion of a plurality of RM3100s permits oversampling with multiple sensors (as opposed to traditional oversampling in time) and an improvement in the resolution of the instrument by a factor of 2 (N improvement, where N is the number of sensors), without sacrificing the sampling frequency necessary to detect ULF waves in the Earth's magnetosphere. Multi-Mag system 20 particularly excels in its low size, cost, and power savings over other magnetometer options. These qualities make Multi-Mag system 20 naturally well suited for CubeSats, for which size, power, and cost are at a premium. In some embodiments, the assembled circuit board 16 of Multi-Mag system 20 can comprise dimensions 10 cm×10 cm×3 cm and a mass, including electronics, of 59.05 g. The footprint was designed such that the instrument can fit into a slot of a 1 U CubeSat of CubeSat magnetometer array system 10.

In some embodiments, microcontroller 18 is operable and configured to synchronize sensor data and provide a flexible, streamlined command interface between the host computer 24 and Multi-Mag system 20. The MSP430 controller product line was specifically chosen for its ultralow-power modes, processing speed, and overall versatility. It has been used in numerous missions, including the first Mars CubeSat mission where two MSP430's coordinated the command and data handling (CDH) system. Controllers in this family have also been irradiated, with the MSP430FR5739 microcontroller surviving up to a TID of nearly 250 krad.

It should be understood that in some embodiments, Multi-Mag system 20 can comprise more than four (4) magnetometers 12 depending on the requirements of the mission and/or application. It is noted that in some embodiments, it may prove beneficial, both in terms of size, cost, and weight, to include an array of RM3100 magnetometers to improve instrument resolution rather than to include a conventional fluxgate. In combination with the development of a new, higher-resolution MI magnetometer, the multi-magnetometer array strategy appears to be a viable low-cost and low-power option for the study of ULF waves, particularly on small satellites or remote, power-constrained ground-based systems.

Although the present embodiment defines the Multi-Mag system 20 as being incorporated in CubeSat form factor, which subjects it to noise from the spacecraft, different approaches have and are being undertaken to solve this issue. A promising solution that has recently been investigated involves using an underdetermined blind source separation (UBSS) algorithm to identify and remove noise generated by various unknown sources.

### Magneto-Inductive Sensing

In some embodiments, each of the plurality of magnetometers 12, being an RM3100 magnetometer, consists of three magneto-inductive (MI) sensors and a single control application-specific integrated circuit (ASIC). The MI sensors are a simple solenoidal coil wrapped around a highly permeable magnetic core. Incorporating the MI sensor with the control ASIC creates the basic resistor-inductor (RL) sensing circuit that drives the MI technology. It should be understood that the present teachings are not limited to PNI Sensor RM3100 magnetometers, but can be used with alternative magnetometers or equivalents. In the interest of clarity, the RM3100 magnetometer will be referenced in the present teachings, but this should not be regarded as limiting unless specifically noted and/or claimed.

Magneto-inductive sensing is predicated on the fact that the induction of a coil wrapped around a highly permeable magnetic core will fluctuate with respect to the magnetic field being applied to the coil. The magnetic field experienced by the coil (H) in turn includes the external field parallel to the coil (H_{E}) and the field generated by current running through the circuit itself (l). It can be represented by the equation H=kl+H_{E}, where k represents the conversion factor of the coil. With this in mind, the inductance of the MI sensor is clearly a function of the magnetic field, as seen in FIG. 2.

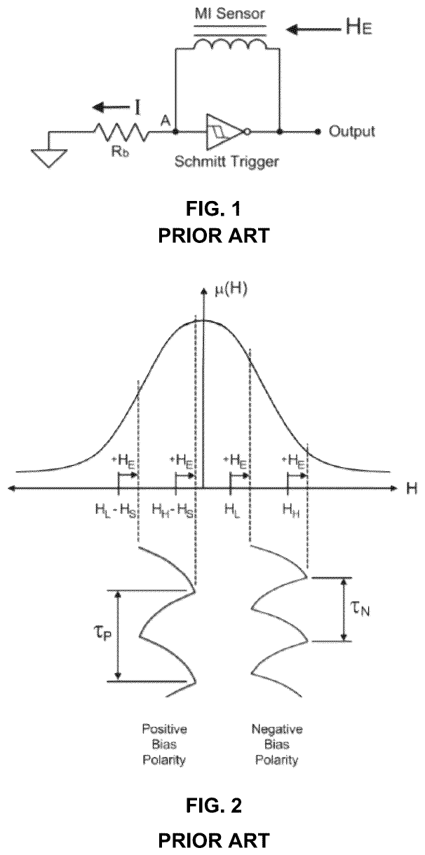

The circuit of magnetometer 12 in FIG. 1 employs a Schmitt trigger with a bias resistor (Rb) and the MI sensor in a feedback loop. It functions as an oscillator whenever a voltage is applied. The period of the circuit's oscillation varies with the inductance of the MI sensing coil and therefore the external field. When no external magnetic field is applied, driving the circuit with a positive (forward) or negative (reverse) voltage will yield the same oscillatory period (T). However, if there is a field present, the oscillatory period for forward biassing the circuit (τₚ) and reverse biassing the circuit (τₙ) will be different (see FIG. 2). Measuring the time to complete a cycle in both directions and taking the difference yields a value that can be directly related to the magnetic field.

The underlying principle of this technology, in which the magnetic field is determined solely by the time difference between forward and reverse biased cycles, provides a completely digital measurement without the use of an analog-to-digital converter (ADC) or an amplifier. Such ADCs and/or amplifiers are weak points of traditional magnetometers, and their elimination significantly decreases the power budget and failure rate of the instrument. Additionally, the simple oscillatory circuit and components that drive the present technology are well-suited for mass production, lowering the cost to produce sensors significantly. These advantages are key criterion for deployment in future multi-CubeSat missions to potentially study the dynamics of planetary magnetospheres and the solar wind.

### Single Sensor Performance

The performance of a single RM3100 magnetometer has been extensively studied previously. Table 1 summarizes the primary characteristics of the sensor.

TABLE 1

| Parameter | Value | |
|---|---|---|
| Dimensions | 2.54 cm × 2.54 cm | |
| Mass | <3 | g |
| Power consumption | <10 | mW |
| Dynamic range | ±100 000 | nT |
| Sampling rate | 40 | Hz |
| Resolution at 40 Hz | 8.73 | nT |
| Resolution at 1 Hz | 2.7 | nT |

| | |
|---|---|
| Noise floor | 4 pT \sqrt{Hz}⁻¹ at 1 Hz |

It should be noted that the demonstrated sampling frequency and corresponding resolution of the sensor is generally ultra-low-frequency (ULF) magnetospheric waves in the PC4-PC5 range. With that said, a resolution improvement of at least 2× is required for deep-space missions where the magnetic field is on the order of 1-10 nT, and upwards of 20× improvement is required for the instrument to observe PC1 waves. The area, weight, and power consumption of the instrument alone, however, open the door to CubeSat missions and power-limited ground-based systems (remotely operated vehicles, planetary landers, or extreme Earth-based environments). The sensor has already been employed in both terrestrial and aeromagnetic geological surveys of iron ore deposits, demonstrating the applicability of the RM3100 to geomagnetic, space physics, or other magnetometer application.

Beyond the baseline features presented in Table 1, a surprising but nonetheless valuable additional characteristic of the RM3100 is its relative radiation hardness. Tests have irradiated nine separate sensors at two facilities using different dose rates up to a total ionizing dose (TID) of at least 300 krad (SI). Of the nine sensors, only two failed during irradiation (the lowest at a TID of 150 krad) with one recovering in the month immediately following exposure. It should also be noted that an appreciable difference in resolution was not observed in comparing pre- and post-irradiation measurements for working magnetometers. Being robust up to 150 krad (SI) enables its use in a variety of space environments including potential missions to the Jovian moons or Van Allen radiation belts where TID is expected to be high for typical mission lengths. In addition, tests for destructive single-event effect susceptibility of the RM3100 magnetometer sensor were conducted using the heavy ion beam at the Lawrence Berkeley National Laboratory's Cyclotron. The tests found no single event latch-up events for LET>75 MeVcm2 mg-1 at an elevated temperature of 85° C.

It is generally understood that the output of RM3100 will be inherently stable over temperature due to the forward or reverse-biassing nature of the MI circuit. Experimentally, this is not what has been observed. Tests are currently being carried out by the University of Michigan Moldwin Magnetics Lab to fully characterize the gain of the sensor over the temperature range −35 to 80° C. Preliminary results show that the thermal gain is significant (roughly 0.5 nT° C.-1) and has some nonlinear behavior. With that said, the nonlinearity is repeatable and consistent, enabling its removal through a simple correction. The fundamental limitation of the RM3100 lies in its inability to detect sub-nanotesla field changes. Low-amplitude ULF waves are currently inaccessible as a result, requiring the instrument to detect wave amplitudes on the order of 0.1 nT.

### Quad-Mag Board

### Operation

Data collection and processing with the instrument is meant to be simple and flexible. Specifically, in some embodiments, microcontroller 18 coordinates the operation thereby enabling all low-level functionality to be abstracted into a single serial byte stream. This serial byte stream employs the Universal Asynchronous Receiver-Transmitter (UART) communication protocol at a speed of 115.2 kbps. Connection to the instrument is then made by a host computer 24 (for a CubeSat this would be the CDH system) at the other end of communication interface 22 (e.g., point-to-point UART bus). The versatility of microcontroller 18 also allows for the serial byte stream to instead use the Serial Peripheral Interface (SPI) protocol or the Inter-Integrated Circuit (I2C) protocol in case of conflicts or need for a higher communication speed. In either case, the system operates in a command/response format.

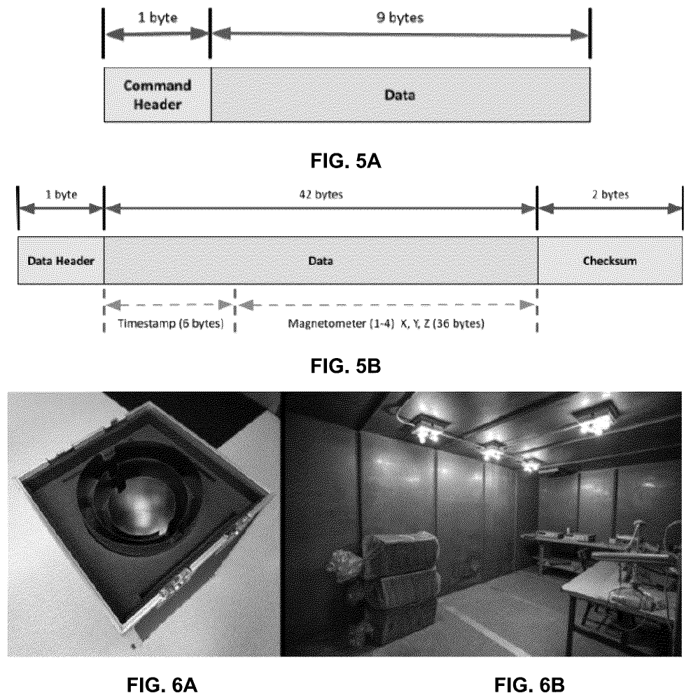

The host computer 24 has access to a preset list of commands that can be sent to and processed by the instrument. Each command then requires a specific response to be sent to the host computer 24 in the form of an acknowledgment or data. The outline of the command/response packets are set forth in FIGS. 5A-5B. The command header is a unique identifier assigned to each of the commands provided to the host computer 24. Similarly, the data header allows the host computer 24 to distinguish between different types of responses provided by the microcontroller 18. These mappings are known prior to operation and enable both the host computer 24 and microcontroller 18 to properly parse the data packet following the header. A checksum is included in the response packet of microcontroller 18 to confirm the integrity of data transmission.

The available commands can be placed into two classes: setup and measurement. Setup commands control the various adjustable parameters of magnetometers 12, e.g., cycle count and sampling rate, while measurement commands simply retrieve data from each of the sensors. The measurement commands can further be broken down into continuous and single mode in which data can be streamed for a period of time for the former or individual measurements can be requested for the latter (particularly useful if an atypical sample rate is desired). Of these two modes, continuous has the most common use case, e.g., if the instrument is functioning as part of an attitude determination and control system (ADCS). Typical operation of the instrument would consist of the host computer 24 sending setup commands (confirming the command was executed via the instrument's response) and then requesting data through a continuous or single-measurement command (which would be followed with a data packet or stream of data packets as outlined in FIG. 5B).

In some embodiments, each of the plurality of RM3100 magnetometers 12 is attached to one of the available MSP430 SPI buses of microcontroller 18, with interrupt lines attached to general purpose in/out (GPIO) pins of the microcontroller 18. When operating in either continuous or single-measurement mode, the plurality of magnetometers are signaled to take readings simultaneously. The interrupt lines of each sensor are asserted when a measurement is ready. This assertion is received through the GPIO of microcontroller 18 and used to precisely timestamp each measurement. The arrival time separation for all magnetometers is typically less than 500 μs. After all magnetometers have been queried and a measurement stored from each, the microcontroller 18 packages the data into the 42-45 byte response packet outlined in FIG. 5B. This packet processing takes on the order of 2-3 ms. The direct consequence of these delays is periodic skipped or missed readings from all the magnetometers. This is clearly apparent in the output data rate of the Multi-Mag system 20 with it being roughly 15% slower than a lone RM3100 magnetometer possessing identical settings (at frequencies below 100 Hz). Despite this, the instrument still easily covers the frequency range necessary to study ULF waves in the Earth's magnetosphere, with a maximum observed sampling rate of roughly 222 Hz querying each axis of all magnetometers.

### Characterization

A single RM3100 magnetometer was previously characterized in a controlled laboratory setting using a number of tests including linearity, frequency response, resolution, stability, and radiation. As stated previously, a complete thermal characterization of an individual sensor is also currently underway. The focus of this research, however, is on improving the resolution of the instrument, and therefore radiation, linearity, and frequency response tests will be omitted in the characterization of the Multi-Mag system 20 presented here. An additional interference test that explores the magnetic influence of multiple sensors and board electronics was also carried out.

Theoretically, placing four, for example, magnetometers on a single board should allow an overall improvement in the resolution of the instrument by a factor of 2 through oversampling with multiple sensors (N improvement, where N is the number of sensors). However, there is the issue of introducing magnetic noise from microcontroller 18 and other components necessary to run the system. In order to mitigate this, Multi-Mag system 20 was designed such that the RM3100's are placed as far away from noise-producing components as possible, i.e., opposite sides of printed circuit board 16 (FIGS. 3A-3B).

The testing presented in the following sections was carried out at the University of Michigan Department of Climate and Space Science and Engineering (CLaSP). Specifically, the tests involved placing the Multi-Mag system 20 and associated CubeSat 10 inside a three-layer p-metal lined zero Gauss chamber that was in turn placed in a p-metal-lined copper room (FIGS. 6A-6B). This is the same setup used by Regoli et al. with the only difference being the Multi-Mag system 20 uses a sampling rate of 65 Hz as opposed to 40 Hz. The higher sampling frequency is a result of using a lower cycle count (400 for all experiments presented here as opposed to 800 previously used). The decision to use this lower cycle count was based on empirically observed lower noise at 1 Hz (post decimation) and the ability to detect higher-frequency signals with the resulting increased sampling rate.

It has already been mentioned that the magnetic field of an MI sensor is a combination of the internal field (generated by electrical components) and the external field. The internal field presents itself as a unique offset inherent to each magnetometer. This offset was calculated by placing the Multi-Mag system 20 inside the zero Gauss chamber and taking the difference between the measured field and the residual field determined by a Meda uMAG fluxgate magnetometer. All data sets presented in this paper have the calculated offsets removed. The values of these offsets generally range from a few hundred to a few thousand nanotesla, depending on the axis. In practice, the internal offset changes slightly after every power cycle of the sensor due to its digital components. As a result, the Multi-Mag system 20 board requires careful calibration if used for absolute field measurements.

### Resolution

Determining the minimum field that can be detected by the instrument is straightforward. The Multi-Mag system 20 was placed inside the zero Gauss chamber in the copper room (FIGS. 6A-6B) such that any remnants of the Earth's magnetic field and other fields generated from nearby current carrying wires (e.g., AC power lines) were sufficiently removed. The resulting time-varying field experienced inside the chamber is well below the noise floor of the instrument.

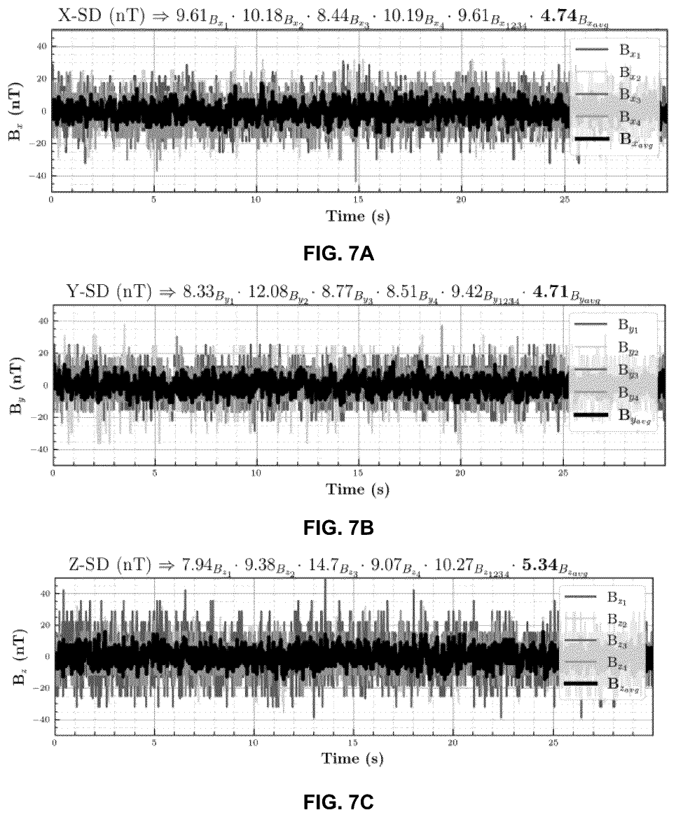

The Multi-Mag system 20 was initially configured to take measurements at a sampling rate of 65 Hz for 30 s. In addition, a 10 min warm-up period was undertaken where data were requested from the sensors but not recorded upon being received. This enables Multi-Mag system 20 and ambient temperature to settle to a constant value such that changes in gain related to temperature could be avoided as much as possible. The standard deviation of the measured signal is accepted as the resolution of the instrument (minimum signal to be detected) for the given sampling frequency. FIGS. 7A-7C display the time series results for this test across all three axes. The plots overlay the measurement taken from each magnetometer 12 and the average of all four measurements (oversampling with all four magnetometers) in different line shades (see legend for details). Additionally, at the top of the plots, the resolution for each individual magnetometer is listed in order, followed by the average of all four resolution values and then the resolution of the combined measurements. The average of all four resolution values is simply an arithmetic mean of the four previously listed standard deviation values. This is compared to the resolution (standard deviation) of the combined measurements where the data sets of all four magnetometers are stacked (i.e., added together along each axis) and the arithmetic mean taken.

There are a few important takeaways from FIGS. 7A-7C. First, the average standard deviation of the axes is relatively close together. There is only a 190 pT difference between the x and y axes and at most an 850 pT difference between the z axis and the other two. Second, when determining the theoretical improvement in resolution for the Multi-Mag system 20, oversampling with four magnetometers should yield a 2× improvement. Comparing the average standard deviation of each axis to the standard deviation of the average of the four measurements, it can be seen that this holds very close to true. The worst improvement in resolution is seen in the z axis of the Multi-Mag system 20 (1.9×), while the other two axes both show nearly exactly a 2× improvement in resolution. The anomalies seen in the z axis can be attributed to the relatively large standard deviation of the third sensor (50% higher than the other three sensor standard deviations).

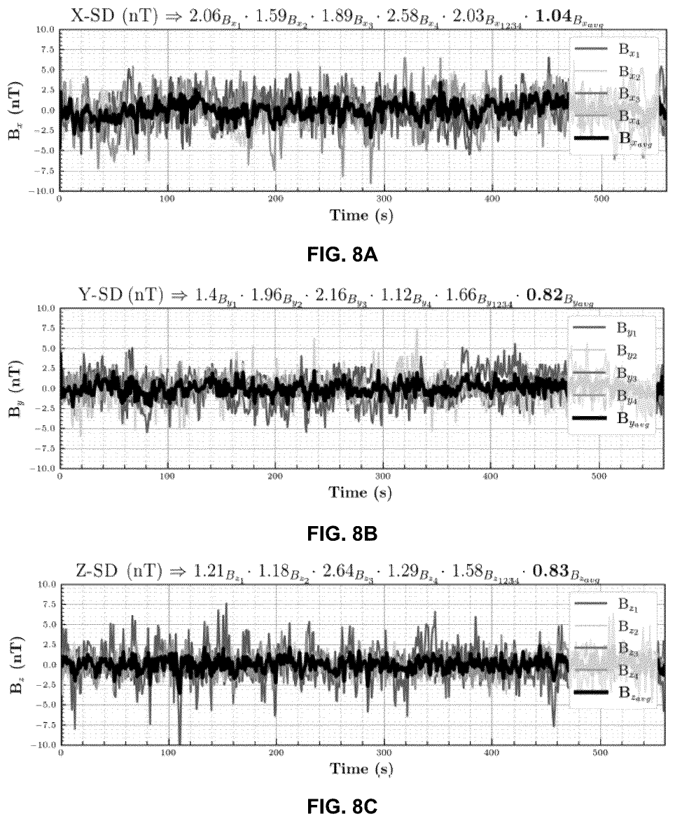

The resolution at 65 Hz for the three axes is taken as 4.74 nT (x axis), 4.71 nT (y axis), and 5.34 nT (z axis). This is already well below the 6.74 nT/LSB (LSB stands for least-significant bit) digital resolution of the instrument. The resolution of the system at 1 Hz was also calculated. To quantify this, a test was run with the Multi-Mag system 20 sampling at 65 Hz for 10 min. The resulting data were then downsampled to 1 Hz using the typical approach of passing the signal through a low-pass filter and then decimating by an integer factor. As with the previously described test, a 10 min warmup period was undertaken immediately before data were collected. The results of this test are shown in FIGS. 8A-8C. As with the previous figure, the plots overlay the measurement taken from each magnetometer as well as the average of all four measurements (oversampling). At the top of each plot is the resolution for all four magnetometers, followed by the average of these four resolutions and then the resolution of the combined measurements.

Although it can be seen in FIGS. 8A-8C, it should be noted that outliers have not been removed from the data (this is most obvious in the z axis time series where multiple single point spikes are present). Interestingly, after decimation, the x axis has the largest standard deviation of the three (this can be attributed to the actual decimation process). As before, the resolution improvement can be quantified by comparing the average standard deviation and the standard deviation of averaging all sensors for each axis. The z axis still shows the largest difference from the theoretical 2× improvement, in this case displaying only a 1.9× improvement in resolution over an individual RM3100. The established resolution at this sampling frequency is taken as 1.04 nT (x axis), 0.82 nT (y axis), and 0.83 nT (z axis).

In addition to establishing the resolution of the Multi-Mag system 20 (standard deviation of the measured signal), it is also valuable to determine the noise floor of the instrument as another performance characteristic. This is calculated from the power spectral density (PSD) of the measured signal inside the zero Gauss chamber in the copper room. The formulation of the PSD is not trivial and there are multiple methods that yield different results. For example, Miles et al. (2019) use a unit-correct implementation of Welch's method (Welch, 1967) that yields a value orders of magnitude higher than the method presented in Regoli et al. (2018b).

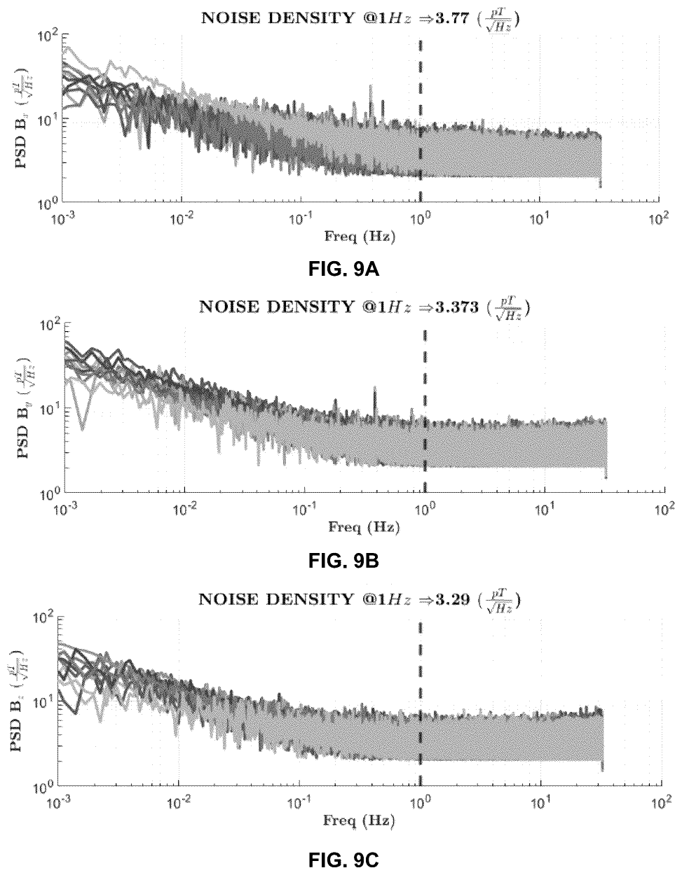

To make a more direct comparison, the present disclosure follows Regoli et al. (2018b) in which the PSD is produced from the Fourier transform of the auto-correlation function of the measured signal. Due to the 1/f dependence of the output, the noise floor of the signal is taken as the value of the PSD at 1 Hz. The system was again configured to sample at 65 Hz, this time for 1 h. The test was run a total of 10 times, and the average of the 10 runs was used. From this, the noise floor of the Multi-Mag system 20 was determined to be 3.770 pT√Hz-1 (x axis), 3.373 pT√Hz-1 (y axis), and 3.290 pT√Hz-1 (z axis) as seen in FIGS. 9A-9C.

### Stability

As noted previously, the Multi-Mag system 20 measurements are not stable between power cycles. The offsets of each sensor axis are different each time the sensor is powered on. This is not an issue in the presented testing as all offsets are removed. In the case of requiring absolute field measurements, however, careful calibration will be needed. Although the offsets are not constant between power cycles, they should be for a single power cycle. This helps define the stability of the sensor, which can be described by the variation in output while experiencing an ideal, constant input. For the Multi-Mag system 20, this can be measured under the condition of the instrument experiencing no external field. Placing the Multi-Mag system 20 inside the zero Gauss chamber inside the copper room achieves this. The system was configured to take measurements at 65 Hz for roughly 38 h.

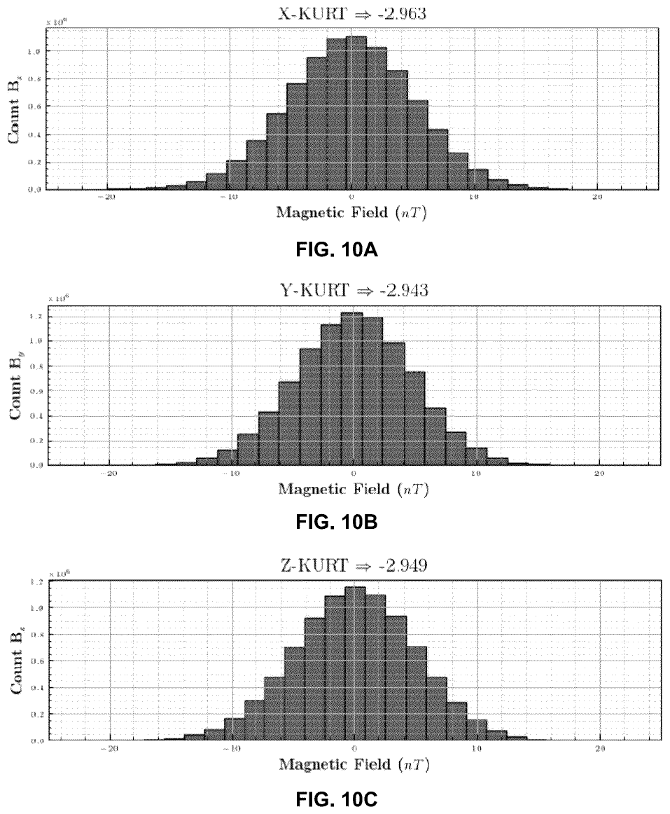

FIGS. 10A-10C display the distribution of measurements from this test for each axis. The bin size was set to 1.685 nT (this is not arbitrary but rather equal to LSB/4). From these figures, the distribution of all axes appear to be Gaussian (as would be expected with white noise). The randomness of the output is confirmed via calculation of the Kurtosis index, which should be close to −3 for a standard normal distribution with light tails. In this test, the indices are −2.963 (x axis), −2.943 (y axis), and −2.949 (z axis). The Multi-Mag system 20 is clearly extremely stable over time.

### Interference

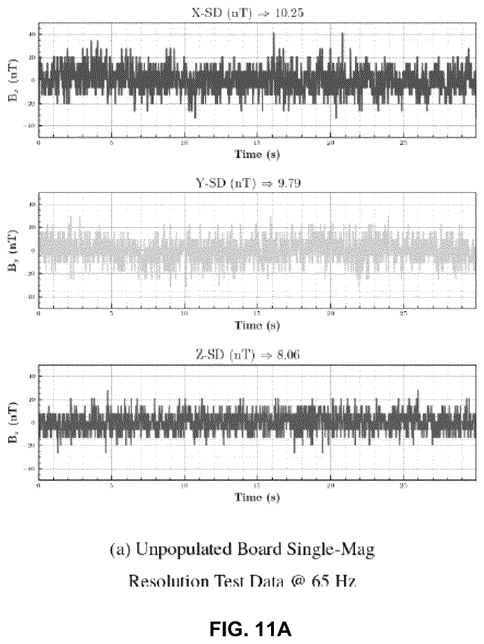

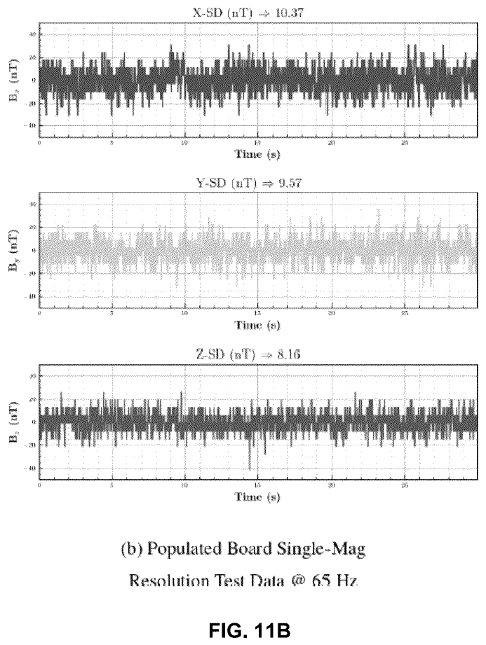

The construction of the Multi-Mag system 20 introduces two potential magnetic noise sources for each of the magnetometers on printed circuit board 16. These two new sources are the companion magnetometers and printed circuit board 16 electronics, respectively. It is well documented that spacecraft and sensor electronics will present an offset in magnetic readings. In this case, the offset is removed and thus unimportant. Rather, the effect on resolution must be quantified. To determine this for companion magnetometers, first a single RM3100 was placed on the Multi-Mag system 20 board inside the zero Gauss chamber in the copper room. Measurements were taken for 30 s at 65 Hz with a 10 min warm-up period immediately prior. Next, all four magnetometers were placed on printed circuit board 16 and similarly configured to sample for 30 s at 65 Hz following a 10 min warm-up period. The results of these two tests are shown in FIG. 11A-11B.

At the top of each plot is the resolution of the specified sensor axis in nT. Direct comparison of FIG. 11A-11B shows minute differences in the resolution for each axis. The most pronounced deviation is in the y axis, where we can see a 0.22 nT variation between the two scenarios. This is well below the established resolution of an individual sensor and clearly implies that multiple magnetometers on the same board do not have significant influence on each other's resolution.

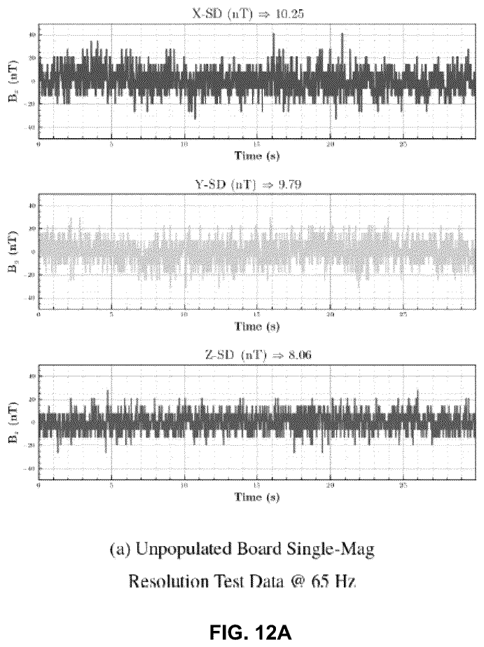

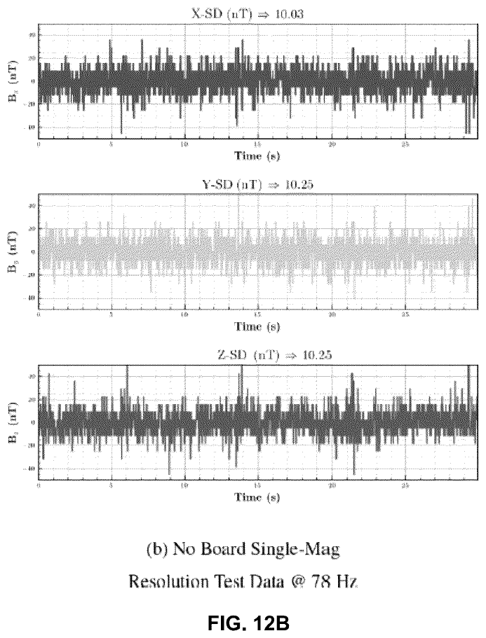

The second potential noise source stems from the controlling electronics on printed circuit board 16, most notably microcontroller 18. To understand the effect of printed circuit board 16 on the resolution of the instrument, it is sufficient to look at its effect on a single magnetometer. This is determined by taking the same magnetometer used for the previous test and placing it inside the zero Gauss chamber in the copper room without the Multi-Mag system 20 present. Measurements were then taken for 30 s, with identical configuration settings as in the prior test. Due to the processing delay introduced by the Multi-Mag system 20, the sampling rate for these measurements is about 15% higher at 78 Hz. A 10 min warm-up period was again undertaken. The results of this test can be seen in FIG. 12B. FIG. 12A is copied from FIG. 11A for ease of comparison. At the top of each plot is the resolution of the specified sensor axis in nanotesla.

The results shown in FIGS. 12A-12B exhibit a 0.22 nT (x axis), 0.46 nT (y axis), and 2.19 nT (z axis) difference in resolution compared to the previous testing setup. Although the largest difference here is 2 orders of magnitude higher than what is seen in FIG. 11A-11B, it is still well below the established resolution of a single magnetometer at these sampling frequencies and thus demonstrates a lack of significant interference generated by printed circuit board 16 electronics. It should also be highlighted that the sampling frequencies in this experiment are not identical due to processing delay introduced by the Multi-Mag system 20. As such, the larger differences in resolution could be explained partly by this disparity.

### Discussion

The characteristics of the Multi-Mag system 20 are in Table 2.

TABLE 2

| Parameter | Value | |
|---|---|---|
| Dimensions | 10 cm × 10 cm × 3 cm | |
| Mass | 59.05 | g |
| Power consumption - Sampling | 23 | mW |
| Power consumption - Inactive | 14 | mW |
| Dynamic range | ±100 000 | nT |
| Sampling rate | 65 | Hz |
| Resolution at 65 Hz (individual axis) | 5.34 | nT |
| Resolution at 1 Hz (individual axis) | 1.04 | nT |

| | |
|---|---|
| Noise floor (individual axis) | 3.77 pT \sqrt{Hz}⁻¹ at 1 Hz |

A standalone RM3100 has a resolution of around 2.2 nT at 1 Hz. The Multi-Mag system 20 of the present teachings reduced that to 1.04 nT or less for each axis through oversampling with four magnetometers. This exceeds the theoretical 2× improvement expected by about 10%. A closer examination of the resolution of each axis on each magnetometer reveals that there is a large disparity between the resolution of individual sensor coils. In fact, the resolution of individual coils was found to vary between 1.12 nT and 2.64 nT at 1 Hz. This disparity most likely arises from variations in the Metglas material of the sensing coil that naturally occur due to the manufacturing process. The consequence of this is that certain sensors perform better or worse than others. Drawing from this conclusion, the extra 10% improvement in resolution was most likely a result of using inherently better RM3100s than used in the initial characterization of Regoli et al. (2018b). The established resolution (Table 2) is therefore taken as an upper limit. Depending on the specific requirements of the measurements, it is recommended that individual RM3100's are characterized in batches of 20 to find the lowest noise and highest-resolution sensors that achieve the best measurements.

In summary, according to the principles of the present teachings in some embodiments, a CubeSat magnetometer board (Multi-Mag system 20) equipped with a plurality of PNI RM3100 magnetometers is provided. The low size, weight, power, and cost of the RM3100 enables the inclusion of four sensors on a single board, allowing a potential factor of 2 reduction in the noise floor established for an individual sensor via oversampling with multiple sensors. The instrument experimentally achieved a noise floor of 5.34 nT (individual axis), averaging across each axis of the four magnetometers, at a 65 Hz sampling rate. This approaches the theoretically established limit for the system of 4.37 nT at 40 Hz. A single onboard Texas Instrument MSP430 microcontroller handles synchronization of the magnetometers and facilitates data collection through a simple UART-based command interface to a host system. The Multi-Mag system 20 has a mass of 59.05 g and total power consumption of 23 mW while sampling and 14 mW while idle. The Multi-Mag system 20 enables nearly 1 nT magnetic field measurements at 1 Hz using commercial off-the-shelf sensors for space applications under optimal conditions.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A magnetometer array system comprising:
a circuit board defining a footprint;
a plurality of magnetometers operably mounted on the circuit board; and
a microcontroller system operably coupled with the plurality of magnetometers, the microcontroller system configured to:
synchronize data from the plurality of magnetometers,
utilize machine learning processes to identify and reduce noise in the synchronized data, and
output a signal representative of a magnetic field with reduced noise due to the machine learning processes; and
a communication interface operably coupled with the microcontroller system configured to communicate the signal.

2. The magnetometer array system according to claim 1 wherein the footprint of the circuit board is sized to be contained with a CubeSat.

3. The magnetometer array system according to claim 1 wherein the circuit board is a singular circuit board having a first side and a second side, each of the plurality of magnetometers being operably mounted on the first side of the singular circuit board.

4. The magnetometer array system according to claim 3 wherein the microcontroller system is operably mounted on the second side of the singular circuit board.

5. The magnetometer array system according to claim 1 wherein the communication interface comprises a Universal Asynchronous Receiver-Transmitter communication interface.

6. The magnetometer array system according to claim 1 wherein the plurality of magnetometers comprises four magnetometers each operably mounted in opposing corners of the circuit board.

7. The magnetometer array system according to claim 1 wherein each of the plurality of magnetometers comprises a magneto-inductive magnetometer.

8. The magnetometer array system according to claim 1 wherein the oversampling with two or more of the plurality of magnetometers comprises oversampling with at least four of the plurality of magnetometers.

9. A CubeSat magnetometer array system comprising:
a housing having CubeSat dimensions;
a host computer; and
a magnetometer array system comprising:
a circuit board mounted within the housing;
a plurality of magnetometers operably mounted on the circuit board; and
a microcontroller system operably coupled with the plurality of magnetometers, the microcontroller system configured to:
synchronize data from the plurality of magnetometers,
utilize machine learning processes to identify and reduce noise in the synchronized data, and
output a signal representative of a magnetic field with reduced noise due to the machine learning processes; and
a communication interface operably coupled with the host computer and the microcontroller system configured to communicate the signal to the host computer.

10. The CubeSat magnetometer array system according to claim 9 wherein the circuit board is a singular circuit board having a first side and a second side, each of the plurality of magnetometers being operably mounted on the first side of the singular circuit board.

11. The CubeSat magnetometer array system according to claim 10 wherein the microcontroller system is operably mounted on the second side of the singular circuit board.

12. The CubeSat magnetometer array system according to claim 9 wherein the communication interface comprises a Universal Asynchronous Receiver-Transmitter communication interface.

13. The CubeSat magnetometer array system according to claim 9 wherein the plurality of magnetometers comprises four magnetometers each operably mounted in opposing corners of the circuit board.

14. The CubeSat magnetometer array system according to claim 9 wherein each of the plurality of magnetometers comprises a magneto-inductive magnetometer.

15. The CubeSat magnetometer array system according to claim 9 wherein the oversampling with two or more of the plurality of magnetometers comprises oversampling with at least four of the plurality of magnetometers.
